(19) United States
(12) Patent Application Publication
(10) Pub. No.: US 2024/0194609 A1
(43) Pub. Date: Jun. 13, 2024

(54) ELECTRONIC DEVICE

(71) Applicant: Advanced Semiconductor Engineering, Inc., Kaohsiung (TW)

(72) Inventors: Han-Chee YEN, Kaohsiung (TW); Ying-Nan LIU, Kaohsiung (TW); Min-Yao CHENG, Kaohsiung (TW); Eelco BERGMAN, Sunnyvale, CA (US)

(73) Assignee: Advanced Semiconductor Engineering, Inc., Kaohsiung (TW)

(21) Appl. No.: 18/076,417

(22) Filed: Dec. 7, 2022

(51) Int. Cl. H01L 23/538; G02B 6/12; H01L 21/48; H01L 21/56; H01L 23/00; H01L 25/00; H01L 25/16; H01L 25/18

(52) U.S. Cl. CPC H01L 23/5389; G02B 6/12004; H01L 21/4857; H01L 21/568; H01L 23/5383; H01L 24/19; H01L 24/20; H01L 25/167; H01L 25/18; H01L 25/50; H01L 24/16; H01L 24/32; H01L 24/73; H01L 2224/16227; H01L 2224/2101; H01L 2224/32225; H01L 2224/73204

(57) ABSTRACT

An electronic device is disclosed. The electronic device includes a first component, a second component, and a first bridge component configured to electrically connect the first component with the second component. The first component is configured to transmit a first signal downwardly without passing the first bridge component and the second component is configured to transmit/receive a second signal to/from outside of the electronic device. A transmission speed of the second signal is higher than a transmission speed of the first signal.

### BACKGROUND

### 1. Field of the Disclosure

The present disclosure relates to an electronic device.

### 2. Description of the Related Art

An interconnect component (such as a substrate, an interposer and a printed circuit board (PCB)) may bridge components and provide electrical connections among the same. Conventionally, power signals and electrical signals (such as high-speed signals) are transmitted through the same surface of the interconnect component. Therefore, input/output (I/O) pins carrying electrical signals may be occupied and limited. In addition, a long signal routing path can result in significant parasitic effect and signal loss, and thus, electronic performance of high-speed data communication may be reduced.

### SUMMARY

In some arrangements, an electronic device includes a first component, a second component, and a first bridge component configured to electrically connect the first component with the second component. The first component is configured to transmit a first signal downwardly without passing the first bridge component and the second component is configured to transmit/receive a second signal to/from outside of the electronic device. A transmission speed of the second signal is higher than a transmission speed of the first signal.

In some arrangements, an electronic device includes a first component, a second component, and a first bridge component configured to electrically connect the first component with the second component. A first circuit region between the first component and the first bridge component has a first density and a second circuit region between the second component and the first bridge component has a second density lower than the first density.

In some arrangements, an electronic device includes an encapsulant, a first bridge component at least partially embedded in the encapsulant, a redistribution layer (RDL) disposed over the encapsulant, and a first electronic component disposed over the RDL. The RDL is configured to provide a first signal path between the first electronic component and the first bridge component, and configured to provide a second signal path between the first bridge component and a component external to the electronic device without passing through the encapsulant

### BRIEF DESCRIPTION OF THE DRAWINGS

Aspects of some arrangements of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an example of an electronic device according to some arrangements of the present disclosure.

FIG. 2 illustrates a cross-sectional view of an example of an electronic device according to some arrangements of the present disclosure.

FIG. 3 illustrates a cross-sectional view of an example of an electronic device according to some arrangements of the present disclosure.

FIG. 4 illustrates a cross-sectional view of an example of an electronic device according to some arrangements of the present disclosure.

FIGS. 5A, 5B, 5C, 5D, 5E, 5F, 5G, 5H, 5I, 5J, 5K, and 5L illustrate cross-sectional views in one or more stages of a method of manufacturing an electronic device in accordance with an embodiment of the present disclosure.

FIGS. 6A, 6B, 6C, 6D, and 6E illustrate cross-sectional views in one or more stages of a method of manufacturing an electronic device in accordance with an embodiment of the present disclosure.

FIGS. 7A, 7B, 7C, 7D, 7E, 7F, 7G, 7H, 7I, 7J, 7K, and 7L illustrate cross-sectional views in one or more stages of a method of manufacturing an electronic device in accordance with an embodiment of the present disclosure.

FIGS. 8A, 8B, 8C, 8D, and 8E illustrate cross-sectional views in one or more stages of a method of manufacturing an electronic device in accordance with an embodiment of the present disclosure.

### DETAILED DESCRIPTION

Common reference numerals are used throughout the drawings and the detailed description to indicate the same or similar components. Arrangements of the present disclosure will be readily understood from the following detailed description taken in conjunction with the accompanying drawings.

The following disclosure provides many different arrangements, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

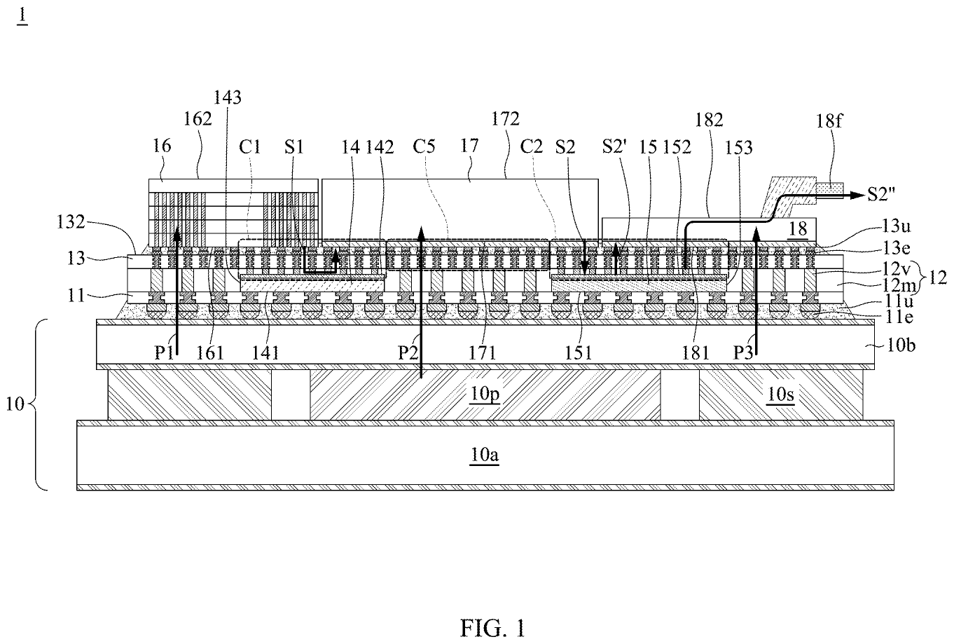

FIG. 1 illustrates a cross-sectional view of an example of an electronic device 1 according to some arrangements of the present disclosure. In some arrangements, the electronic device 1 may include a package, such as a semiconductor device package. The electronic device 1 may include a carrier 10, interconnection structures 11, 12, 13, bridge components 14, 15, electronic components 16, 17, and a photonic component 18.

The carrier 10 may include substrates 10a and 10b. In some arrangements, the substrates 10a and 10b may each include, for example, a printed circuit board (PCB), such as a paper-based copper foil laminate, a composite copper foil laminate, or a polymer-impregnated glass-fiber-based copper foil laminate.

In some arrangements, the electronic device 1 may include other peripheral devices or computer hardware such as a hard disk, an input device, an output device, a memory device, a communication device, etc. In some arrangements, the substrate 10a may include a system board, a main board, a main PCB, and so on. The substrate 10a may provide slots, sockets, and/or connectors for connecting the other peripheral devices or computer hardware.

The substrate 10b may be disposed over or on the substrate 10a. A dimension (e.g., a thickness, a width, and/or cross-section area) of the substrate 10b may be less than that of the substrate 10a. The substrate 10b may be operatively coupled (e.g., mated) to the substrate 10a using a connector 10s. The connector 10s may include a slot, a socket, or another type of connector for connecting the substrate 10b with the substrate 10a.

A power regulating device 10p may be disposed over or on the substrate 10a. The power regulating device 10p may be disposed between the substrates 10a and 10b. The power regulating device 10p may be electrically connected with the interconnection structure 11 through the substrate 10b.

In some arrangements, the power regulating device 10p may include a multiphase controller or a power controller. In some arrangements, the power regulating device 10p may include a power management integrated circuit (PMIC). In some arrangements, the power regulating device 10p may include a voltage regulator, such as a linear regulator (which is configured to maintain a constant output voltage) or a switching regulator (which is configured to generate an output voltage higher than or lower than the input voltage). In some arrangements, the power regulating device 10p may include a step-down (buck) converter, a step-up (boost) converter, an analog-to-digital converter, a digital-to-analog converter, an AC-DC converter, a DC-DC converter, other types of converters, or a combination thereof.

In some arrangements, the carrier 10 may provide power and/or ground connections to the devices or components (such as the electronic components 16, 17, and the photonic component 18) electrically connected to the carrier 10.

For example, the carrier 10 may have a connector or terminal configured to be electrically connected to a power source or a power supply (not illustrated in the figures). The carrier 10 may provide a power routing path (or a power path) between the power supply and the power regulating device 10p, which in turn may provide regulated power to one or more of the electronic components 16, 17, and the photonic component 18. For example, the power regulating device 10p may be configured to provide regulated power for charging and/or operating the electronic component 16 via the power path P1. For example, the power regulating device 10p may be configured to provide regulated power for charging and/or operating the electronic component 17 via the power path P2. For example, the power regulating device 10p may be configured to provide regulated power for charging and/or operating the photonic component 18 via the power path P3.

In some arrangements, the power regulating device 10p may partially overlap with an active surface (such as the surface 171) of the electronic component 17 vertically, or in a direction substantially perpendicular to a surface 132 of the interconnection structure 13 over which the electronic component 17 is disposed.

The power paths P1, P2, and P3 may be provided, defined, constructed, or established by the substrate 10b, and the interconnection structures 11, 12, and 13. The power path P2 between the power regulating device 10p and the electronic component 17 may be substantially perpendicular to the surface 132 of the interconnection structure 13.

The power path P2 between the power regulating device 10p and the electronic component 17 may be substantially perpendicular to the active surface (such as the surface 171) of the electronic component 17. The power path P2 between the power regulating device 10p and the electronic component 17 may be vertically oriented with respect to the active surface (such as the surface 171) of the electronic component 17. As such, the power path P2 may be shorter and the voltage drop thereof may be reduced in comparison with a comparative embodiment where the power transmission path or direction is not vertically oriented with respect to the active surface (such as the surface 171) of the electronic component 17.

As used herein, a power path may refer to a path dedicated to power supply connections. As used herein, a signal path may refer to a path through which an electrical signal (e.g., that conveys information or data) may be transmitted. Such an electrical signal may include either analog or digital signals.

The positions and number of the substrates 10a and 10b, and the power regulating device 10p in the electronic device 1 are not intended to limit the present disclosure. For example, there may be any number of substrate(s) in the electronic device 1 due to design needs. For example, there may be any number of power regulating device(s) in the electronic device 1 due to design needs.

The interconnection structure 11 may be electrically connected to the substrate 10b using electrical contacts 11e over (e.g., contacting directly) the substrate 10b. In some arrangements, the electrical contacts lie may include a solder ball, such as a controlled collapse chip connection (C4) bump, a ball grid array (BGA), a land grid array (LGA), and so on. In some arrangements, the electrical contacts 11e may include a conductive pad, a conductive via, a conductive pillar, a conductive wire, or a combination thereof. An underfill 11u may be disposed between the interconnection structure 11 and the substrate 10b to cover or encapsulate the electrical contacts 11e.

The interconnection structure 11 may include an interconnection layer (e.g., redistribution layer, RDL) and a dielectric layer. A portion of the RDL may be covered or encapsulated by the dielectric layer while another portion of the RDL may be exposed from the dielectric layer to provide input/output (I/O) access, such as I/O pads. For example, the interconnection structure 11 may be configured to electrically connect one or more of the interconnection structure 12, the bridge component 14, and the bridge component 15 with the substrate 10b. For example, the interconnection structure 11 may be configured to provide electrical connections between the substrate 10b and the interconnection structure 12, electrical connections between the substrate 10b and the bridge component 14, and electrical connections between the substrate 10b and the bridge component 15.

The interconnection structure 12 may be disposed over or on the interconnection structure 11. The interconnection structure 12 may be disposed between the interconnection structure 11 and the interconnection structure 13.

The interconnection structure 12 may include an encapsulant 12m and one or more conductive elements 12v. In some arrangements, the encapsulant 12m may include an epoxy resin having fillers, a molding compound (e.g., an epoxy molding compound or another molding compound), a polyimide, a phenolic compound or material, a material with a silicone dispersed therein, or a combination thereof. The encapsulant 12m and the dielectric layer of the interconnection structure 11 may include different materials.

The conductive element 12v may penetrate the encapsulant 12m. The conductive element 12v may include a conductive pillar, a conductive via (such as a through mold via (TMV)), a conductive trace, a conductive wire, or other feasible connectors. In some arrangements, the conductive element 12v may be electrically connected to the interconnection structure 11 (such as to the RDL). The conductive element 12v may extend between the interconnection structure 11 and the interconnection structure 13. In some arrangements, the conductive element 12v may taper toward the interconnection structure 11. In some arrangements, the conductive element 12v may taper toward the interconnection structure 13. In some arrangements, the conductive element 12v may have a constant width.

The bridge component 14 may be at least partially embedded in the interconnection structure 12. The bridge component 14 may be entirely embedded in the interconnection structure 12. The bridge component 14 may have a surface 141 facing the substrate 10b, a surface 142 opposite to the surface 141, and a lateral surface 143 extending between the surface 141 and the surface 142. The surface 142 may face the electronic components 16 and 17.

The bridge component 14 may be at least partially covered or surrounded by the encapsulant 12m of the interconnection structure 12. For example, the surface 142 and the lateral surface 143 may be at least partially covered or surrounded by the encapsulant 12m of the interconnection structure 12. In some arrangements, the surface 141 of the bridge component 14 may be at least partially exposed from the encapsulant 12m of the interconnection structure 12 and contact the interconnection structure 11.

The conductive element 12v may extend along the lateral surface 143 of the bridge component 14. The height or thickness of the conductive element 12v may be greater than the height or thickness of the bridge component 14. For example, the conductive element 12v may extend from the same elevation as the surface 141 of the bridge component 14 to an elevation higher than the surface 142 of the bridge component 14. For example, the conductive element 12v may extend beyond the surface 142 of the bridge component 14.

The bridge component 14 may include a passive component or a passive bridge component, which may not require an external power source to function and may not provide electrical gain.

The bridge component 14 may include a semiconductor substrate. The semiconductor substrate materials may include, but are not limited to, silicon (Si), Silicon on insulator (SOI), germanium (Ge), indium phosphide (InP), gallium arsenide (GaAs), gallium nitride (GaN), etc.

An interconnection layer (e.g., an RDL) may be disposed over or on the surface 142 of the bridge component 14. Electrical or contact terminals such as contact pads, conductive studs or conductive pillars may be disposed over or on the surface 142, for transmission of electrical signals between the electronic components 16 and 17. For example, the bridge component 14 may be configured to provide, define, construct, or establish at least a part of the signal path S1 between the electronic components 16 and 17. For example, the bridge component 14 may be configured to function as a signal transmitting element between the electronic components 16 and 17.

The bridge component 15 may be at least partially embedded in the interconnection structure 12. The bridge component 15 may be entirely embedded in the interconnection structure 12. The bridge component 15 may have a surface 151 facing the substrate 10b, a surface 152 opposite to the surface 151, and a lateral surface 153 extending between the surface 151 and the surface 152. The surface 152 may face the electronic component 17 and the photonic component 18.

In a direction substantially perpendicular to the surface 132 (the surfaces 151, 152, 171, 172, 181, and/or 182), the overlapping area between the bridge component 15 and the electronic component 17 may be different from the overlapping area between the bridge component 15 and the photonic component 18. For example, the overlapping area between the bridge component 15 and the electronic component 17 may be smaller than the overlapping area between the bridge component 15 and the photonic component 18. For example, the interface between the bridge component 15 and the electronic component 17 may be smaller than the interface between the bridge component 15 and the photonic component 18.

The bridge component 15 may be at least partially covered or surrounded by the encapsulant 12m of the interconnection structure 12. For example, the surface 152 and the lateral surface 153 may be at least partially covered or surrounded by the encapsulant 12m of the interconnection structure 12. In some arrangements, the surface 151 of the bridge component 15 may be at least partially exposed from the encapsulant 12m of the interconnection structure 12 and contact the interconnection structure 11.

The bridge component 15 and the bridge component 14 may be separated by the encapsulant 12m of the interconnection structure 12. The conductive element 12v may be disposed between the bridge component 15 and the bridge component 14. The power path P2 between the power regulating device 10p and the electronic component 17 may pass through the conductive element 12v between the bridge component 15 and the bridge component 14.

The conductive element 12v may extend along the lateral surface 153 of the bridge component 15. The height or thickness of the conductive element 12v may be greater than the height or thickness of the bridge component 15. For example, the conductive element 12v may extend from the same elevation as the surface 151 of the bridge component 15 to an elevation higher than the surface 152 of the bridge component 15. For example, the conductive element 12v may extend beyond the surface 152 of the bridge component 15.

The bridge component 15 may include an active component or an active bridge component, which may rely on an external power supply to process electrical signals. The bridge component 15 may include an electronic integrated circuit (EIC), a photonic integrated circuit (PIC), an integrated electronic-photonic integrated circuit (EPIC), an input/output (I/O) die, or a combination thereof. The bridge component 15 may be a chip or a die including a semiconductor substrate, one or more integrated circuit devices and one or more overlying interconnection layers therein. The integrated circuit devices may include active devices such as diodes, transistors and/or passive devices such as resistors, capacitors, inductors, or a combination thereof.

An interconnection layer (e.g., an RDL) may be disposed over or on the surface 152 of the bridge component 15. Electrical or contact terminals such as contact pads, conductive studs or conductive pillars may be disposed over or on the surface 152, for transmission of electrical signals between the electronic component 17 and the photonic component 18. For example, the bridge component 15 may be configured to provide, define, construct, or establish at least a part of the signal paths S2 and S2′ between the electronic component 17 and the photonic component 18. For example, the bridge component 15 may be configured to function as a signal transmitting element between the electronic component 17 and the photonic component 18.

The bridge component 15 and the bridge component 14 may be products from different process nodes. For example, the process node used to design and fabricate the bridge component 15 may be different from the process node used to design and fabricate the bridge component 14. The line widths of wafers, photomasks, or reticles used to manufacture the bridge component 15 may be different from the line widths of wafers, photomasks, or reticles used to manufacture the bridge component 14.

The interconnection structure 13 may be disposed over or on the interconnection structure 12. The interconnection structure 13 may be similar to the interconnection structure 11. Therefore, some details may correspond to the paragraphs above, and a description thereof is not repeated hereinafter for conciseness.

The interconnection structure 13 may be configured to electrically connect the electronic component 16 with at least one of the interconnection structure 12 and the bridge component 14. The interconnection structure 13 may be configured to electrically connect the electronic component 17 with one or more of the interconnection structure 12, the bridge component 14, and the bridge component 15. The interconnection structure 13 may be configured to electrically connect the photonic component 18 with at least one of the interconnection structure 12 and the bridge component 15.

The interconnection structure 13 may include a circuit region C1 over the bridge component 14, a circuit region C2 over the bridge component 15, and a circuit region C5 under the electronic component 17. The circuit region C1 may partially overlap with the active surface (such as the surface 161) of the electronic component 16 vertically, or in a direction substantially perpendicular to the surface 132 of the interconnection structure 13. The circuit region C1 may partially overlap with the active surface (such as the surface 171) of the electronic component 17 vertically, or in a direction substantially perpendicular to the surface 132 of the interconnection structure 13.

In some arrangements, a portion of the interconnection structure 13, the RDL of the bridge component 14, a portion of the active surface (such as the surface 161) of the electronic component 16, and a portion of the active surface (such as the surface 171) of the electronic component 17 may collectively form the circuit region C1.

The circuit region C2 may partially overlap with the active surface (such as the surface 171) of the electronic component 17 vertically, or in a direction substantially perpendicular to the surface 132 of the interconnection structure 13. The circuit region C2 may partially overlap with the active surface (such as the surface 181) of the photonic component 18 vertically, or in a direction substantially perpendicular to the surface 132 of the interconnection structure 13.

In some arrangements, a portion of the interconnection structure 13, the RDL of the bridge component 15, a portion of the active surface (such as the surface 171) of the electronic component 17, and a portion of the (such as the surface 181) of the photonic component 18 may collectively form the circuit region C2.

The circuit region C5 may partially overlap with the active surface (such as the surface 171) of the electronic component 17 vertically, or in a direction substantially perpendicular to the surface 132 of the interconnection structure 13.

The circuit region C1 may be configured to provide at least a part of the signal path S1 between the electronic component 16 and the electronic component 17. The circuit region C2 may be configured to provide at least a part of the signal paths S2 and S2′ between the electronic component 17 and the photonic component 18. The circuit region C5 may be configured to provide at least a part of the power path P2 between the power regulating device 10p and the electronic component 17.

In some arrangements, the electronic component 17 may be configured to communicate with external component(s) through the signal paths S2, S2′, and S2″. Therefore, the circuit region C2 may be configured to provide at least a part of an external signal path of the electronic component 17, such as a signal path from the electronic component 17 to the outside of the electronic device 1, and vice versa.

The circuit region C1 and the circuit region C2 may have different circuit densities. For example, the circuit region C2 may have a circuit density higher than that of the circuit region C1. For example, the line width (e.g., the width of a line), the line spacing (e.g., the distance or the pitch between two adjacent lines), and/or the pad pitch (e.g., the distance or pitch between two adjacent pads) in the circuit region C2 may be less than those of the circuit region C1. In some arrangements, the circuit region C2 may be configured to support high-speed data transmission or communication. For example, the data transmission speed of the circuit region C2 may be higher than the data transmission speed of the circuit region C1.

The circuit region C1 and the circuit region C5 may have different circuit densities. For example, the circuit region C1 may have a circuit density higher than that of the circuit region C5. For example, the line width (e.g., the width of a line), the line spacing (e.g., the distance or the pitch between two adjacent lines), and/or the pad pitch (e.g., the distance or pitch between two adjacent pads) in the circuit region C1 may be less than those of the circuit region C5. The data transmission speed of the circuit region C2 may be higher than the data transmission speed of the circuit region C5.

In some arrangements, the interconnection structures 11, 12, and 13 may be collectively referred to as a circuit structure that may facilitate and allow communications among the components mounted over it. The bridge components 14 and 15 may each be at least partially embedded or integrated in the circuit structure.

The electronic component 16 may be disposed over or on the interconnection structure 13. The electronic component 16 may be electrically connected to the interconnection structure 13 through solder bonding, Cu-to-Cu bonding, or hybrid bonding. For example, the electronic component 16 may be electrically connected to the interconnection structure 13 using electrical contacts 13e over (e.g., contacting directly) the substrate 10b. An underfill 13u may be disposed over the interconnection structure 13 to cover or encapsulate the electrical contacts 13e.

The electronic component 16 may include a surface 161 facing the bridge component 14 and a surface 162 opposite to the surface 161 and facing away from the bridge component 14. In some arrangements, the surface 161 may include an active surface and the surface 162 may include a backside surface.

The electronic component 16 may include a non-transitory memory or a non-volatile memory (such as a flash memory and a read-only memory (ROM)) or a volatile memory (such as a Dynamic Random Access Memory (DRAM)). In some arrangements, the electronic component 16 may include a high bandwidth memory (HBM). In some arrangements, the electronic component 16 may be configured to be accessed by the electronic component 17. The electronic component 16 may be configured to support data storage and retrieval operations with the electronic component 17.

The electronic component 17 may be disposed over or on the interconnection structure 13. The electronic component 17 may be electrically connected to the interconnection structure 13 through solder bonding, Cu-to-Cu bonding, or hybrid bonding. For example, the electronic component 17 may be electrically connected to the interconnection structure 13 using the electrical contacts 13e over (e.g., contacting directly) the interconnection structure 13.

The electronic component 17 may include a surface 171 facing the bridge components 14 and 15, and a surface 172 opposite to the surface 171 and facing away from the bridge components 14 and 15. In some arrangements, the surface 171 may include an active surface and the surface 172 may include a backside surface.

The electronic component 17 may include a processor, a controller, or an input/output (I/O) buffer, etc. In some arrangements, the electronic component 17 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of computing element or integrated circuit. The electronic component 17 may be configured to electrically connect with the electronic component 16 through the circuit region C1, to electrically connect with the carrier 10 through the circuit region C5, and to electrically connect with the photonic component 18 through the circuit region C2.

The data transmission speed between the electronic component 17 and the photonic component 18 may be higher than the data transmission speed between the electronic component 17 and the carrier 10. The data transmission speed of the circuit region C2 may be higher than the data transmission speed of the circuit region C5. In some arrangements, the signal path between the electronic component 17 and the carrier 10 may not pass the bridge component 15. For example, the signal path between the electronic component 17 and the carrier 10 may pass along at least a side of the bridge component 15. For example, the electronic component 17 may be configured to transmit a signal downwardly without passing the bridge component 15.

The signal path between the electronic component 16 and the electronic component 17 may include a vertical path (e.g., a part of the signal path S1 via the circuit region C1 of the interconnection structure 13) for transmitting the electrical signal from the electronic component 16 downwardly toward the bridge component 14, a horizontal or lateral path (e.g., a part of the signal path S1 via the RDL of the bridge component 14) for transmitting the electrical signal from under the electronic component 16 toward the bottom or the underside of the electronic component 17, and a vertical path (e.g., a part of the signal path S1 via the circuit region C1 of the interconnection structure 13) for transmitting the electrical signal upwardly from the bridge component 14 toward the electronic component 17. For example, the part of the signal path S1 provided by the bridge component 14 may include a horizontal or lateral path.

The bridge component 14 may be configured to receive an electrical signal from the electronic component 16 and transmit the same electrical signal toward the electronic component 17 without processing the electrical signal. For example, the bridge component 14 may consume or store at least a part of the energy of the electrical signal from the electronic component 16. However, the bridge component 14 may not change or alter the information or data of the electrical signal from the electronic component 16.

The photonic component 18 may be disposed over or on the interconnection structure 13. The photonic component 18 may be electrically connected to the interconnection structure 13 through solder bonding, Cu-to-Cu bonding, or hybrid bonding. For example, the photonic component 18 may be electrically connected to the interconnection structure 13 using the electrical contacts 13e over (e.g., contacting directly) the substrate 10b.

The photonic component 18 may include a silicon photonics substrate, and one or more optical devices and/or photonic integrated circuits. In some arrangements, the silicon photonics substrate may include a Silicon on Insulator (SOI) substrate including a silicon substrate, an oxide layer disposed on the silicon substrate, and a silicon layer disposed on the oxide layer. Examples of the optical devices and/or photonic integrated circuits may include an optical transmitter, an optical receiver, an optical transceiver, optical waveguides, optical gratings, optical resonators, optical multiplexers, optical demultiplexers, optical modulators, optical switches, optical transducers, and so on.

The photonic component 18 may have a surface 181 facing the surface 152 of the bridge component 15 and a surface 182 opposite to the surface 181. The surface 181 of the photonic component 18 and the surface 152 of the bridge component 15 may include active surfaces. The surface 182 of the photonic component 18 and the surface 151 of the bridge component 15 may include backside surfaces. The active surfaces of the photonic component 18 and the bridge component 15 may face toward each other.

As used herein, the term “active side” or “active surface” of a component may refer to a side or a surface of a component over which electrical or contact terminals such as contact pads, conductive studs or conductive pillars are disposed, for transmission of electrical signals or power. The “backside,” “inactive side,” or “inactive surface” of a component may refer to a surface of the component over which no contact terminals are disposed.

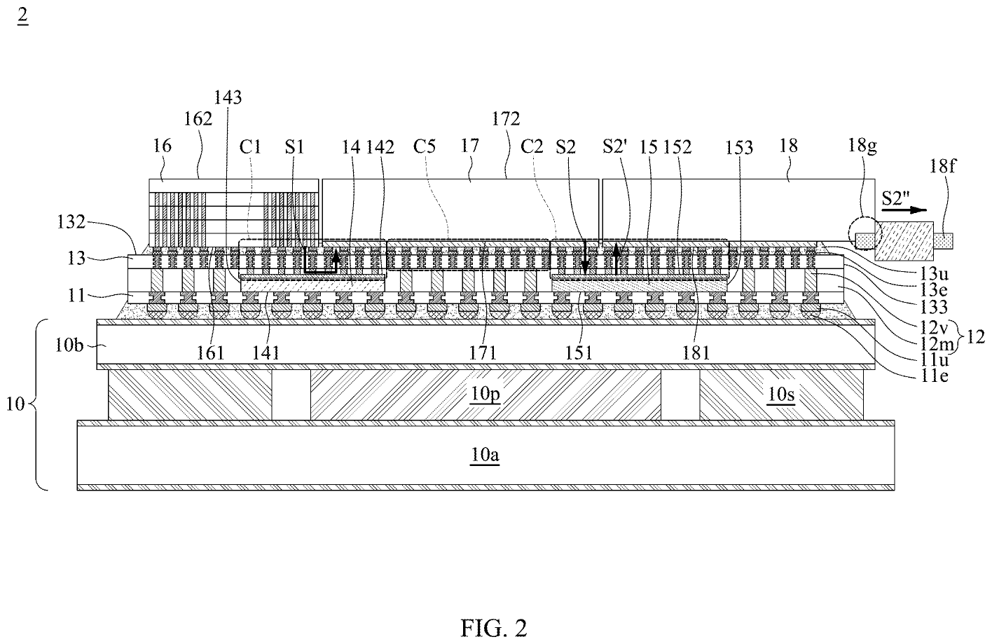

An optical fiber 18f may be coupled to the surface 182 of the photonic component 18 through, for example, an optical grating and/or an optical waveguide. The position and number of the optical fiber are not intended to limit the present disclosure. For example, the optical fiber 18f may be coupled to the photonic component 18 through edge coupling, as shown in FIG. 2.

In some arrangements, the photonic component 18 and the bridge component 15 may be configured to perform photonic data transmission (such as high-speed data transmission or communication) between the electronic device 1 and external component(s). For example, the photonic component 18 and the bridge component 15 may allow for a photonic data transmission between the electronic device 1 and external component(s). For example, the photonic component 18 and the bridge component 15 may function as a photonic data transmission structure. For example, the photonic component 18 and the bridge component 15 may function as an optical/electrical (O/E) converter and/or an electrical/optical (E/O) converter. In some arrangements, the photonic component 18 may include an O/E converter and/or an E/O converter.

The photonic component 18 may be configured to generate, guide, manipulate, modulate, detect, or process light in any suitable fashion. The photonic component 18 may be configured to process signals imposed on optical beams while the bridge component 15 may process signals imposed on electrical currents or voltages.

For example, the bridge component 15 may be configured to receive an electrical signal from the electronic component 17 (such as via the signal path S2), process the electrical signal, and generate a processed electrical signal for the photonic component 18 (e.g., via the signal path S2′). For example, the bridge component 15 may be capable of controlling, analyzing, modifying, amplifying, and synthesizing the electrical signal from the electronic component 17.

The photonic component 18 may receive the processed electrical signal from the bridge component 15 (e.g., via the signal path S2′), perform electrical to optical data conversion, and output the optical signal toward the outside of the electronic device 1 through the optical fiber 18f (such as via the signal path S2″).

In an opposite transmission direction, the photonic component 18 may receive an optical signal from outside of the electronic device 1 through the optical fiber 18f (such as via the signal path S2″ in an opposite transmission direction), perform optical to electrical data conversion, and transmit an electrical signal to the bridge component 15 (such as via the signal path S2′ in an opposite transmission direction). The bridge component 15 may receive the electrical signal from the photonic component 18, process the electrical signal, and transmit the processed electrical signal to the electronic component 17 (such as via the signal path S2 in an opposite transmission direction) such that the electronic device 1 may perform an instruction accordingly.

In some arrangements, the signal path between the electronic component 17 and the photonic component 18 may include a vertical path (e.g., the signal path S2 via the circuit region C2 of the interconnection structure 13) for transmitting the electrical signal from the electronic component 17 downwardly toward the bridge component 15 and a vertical path (e.g., the signal path S2′ via the circuit region C2 of the interconnection structure 13) for transmitting the processed electrical signal from the bridge component 15 upwardly toward the photonic component 18.

Since the bridge component 15 may include an active bridge component, the high-speed data transmission or communication between the photonic component 18 and the electronic component 17 may be provided by the active circuit of the bridge component 15. The bridge component 15 may generate a processed electrical signal for the photonic component 18 based on an electrical signal from the electronic component 17 without horizontally or laterally transmitting the electrical signal and/or the processed electrical signal.

For example, the part of the signal paths S2 and S2′ provided by the bridge component 15 may include a vertical path. There may be no horizontal or lateral paths in the part of the signal paths S2 and S2′ provided by the bridge component 15. Therefore, the signal path between the electronic component 17 and the photonic component 18 can be short and signal propagation delay can be reduced. For example, the data transmission speed between the electronic component 17 and the photonic component 18 may be higher than the data transmission speed between the electronic component 17 and the electronic component 16.

According to some arrangements of the present disclosure, by embedding the bridge component 15 in the circuit structure (which may include the interconnection structures 11, 12, and 13) and using the photonic component 18 and the bridge component 15 to perform photonic data transmission (such as high-speed data transmission) between the electronic device 1 and external component(s), the package size of the electronic device 1 can be reduced and the data transmission speed of electronic device 1 can be enhanced.

In addition, since the bridge component 15 is an active bridge component 15, the signal paths S2 and S2′ between the electronic component 17 and the photonic component 18 can be exclusive of a horizontal or lateral direction, and the signal paths S2 and S2′ can be short and signal propagation delay can be reduced. Therefore, the data transmission speed of electronic device 1 can be significantly increased.

Furthermore, the photonic data transmission between the electronic device 1 and external component(s) can be transmitted without passing through the carrier 10. Therefore, the issue of interference (such as noise or interference generated from the EMI field) between the power path and the non-power path (such as the signal path) can be significantly reduced or alleviated. More I/O pins can be provided on the carrier 10 to transmit electrical signals without increasing interference. Therefore, the performance of the electronic device 10 can be enhanced and the space efficacy can be improved.

FIG. 2 illustrates a cross-sectional view of an example of an electronic device 2 according to some arrangements of the present disclosure. The electronic device 2 in FIG. 2 is similar to the electronic device 1 in FIG. 1 except that the optical fiber 18f may be coupled to the photonic component 18 through edge coupling. The photonic component 18 may include a groove 18g for aligning and accommodating the optical fiber 18f. The photonic component 18 may include an overhanging structure extending beyond a lateral surface 133 of the interconnection structure 13.

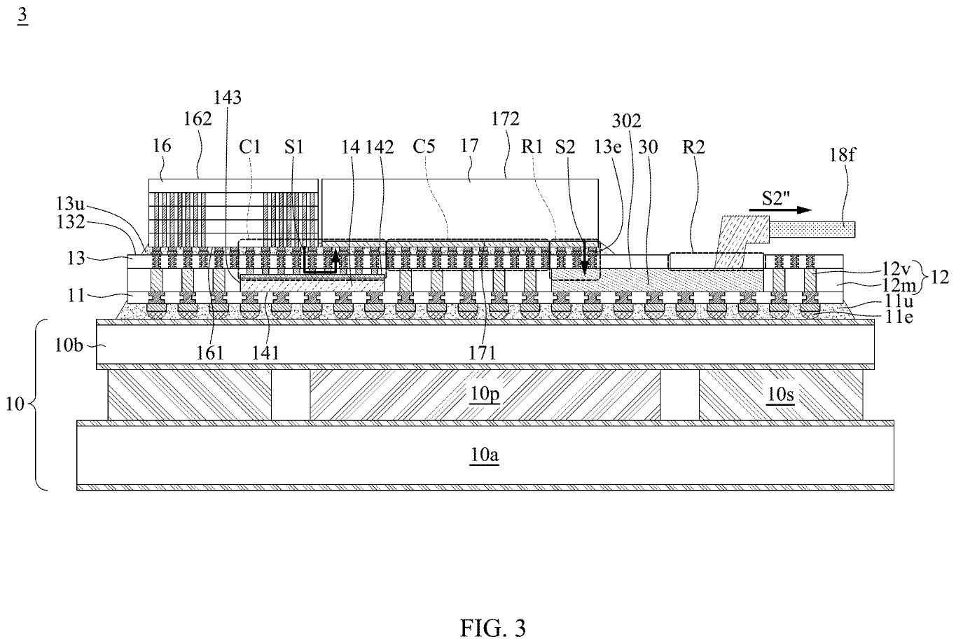

FIG. 3 illustrates a cross-sectional view of an example of an electronic device 3 according to some arrangements of the present disclosure. The electronic device 3 in FIG. 3 is similar to the electronic device 1 in FIG. 1 except that the photonic component 18 and the bridge component 15 in the electronic device 1 are replaced by an integrated component 30. The integrated component 30 may include an integrated electronic-photonic integrated circuit (EPIC). The integrated component 30 may be configured to perform photonic data transmission (such as high-speed data transmission) between the electronic device 3 and external component(s).

The optical fiber 18f may be coupled to a surface 302 of the integrated component 30 through, for example, an optical grating and/or an optical waveguide. In some arrangements, the surface 302 may include an active surface.

The integrated component 30 may include an electrical transmission region R1 under the electronic component 17. The electrical transmission region R1 may be similar to the circuit region C2 in FIG. 1. The electrical transmission region R1 may be electrically connected to the electronic component 17 through the RDL of the interconnection structure 13. The electrical transmission region R1 may be configured to receive the electrical signal from the electronic component 17. The electrical transmission region R1 may contact the RDL of the interconnection structure 13.

The integrated component 30 may include an optical transmission region R2 different from the electrical transmission region. The optical transmission region R2 may be at least partially exposed from the RDL of the interconnection structure 13. The optical transmission region R2 may be configured to generate, guide, manipulate, modulate, detect, or process light in any suitable fashion. The optical fiber 18f may be coupled to the optical transmission region R2. The electrical transmission region R1 may be configured to transmit the electrical signal between the electronic component 17 and the optical transmission region R2. The electrical transmission region R1 may function as a bridge circuit between the electronic component 17 and the optical transmission region R2.

In some arrangements, by integrating the photonic component and the electronic component on a same chip, the high-speed data transmission of photonics may be combined with the high-speed data processing of electronics. The performance of the electronic device 3 can be enhanced and the space efficiency can be improved.

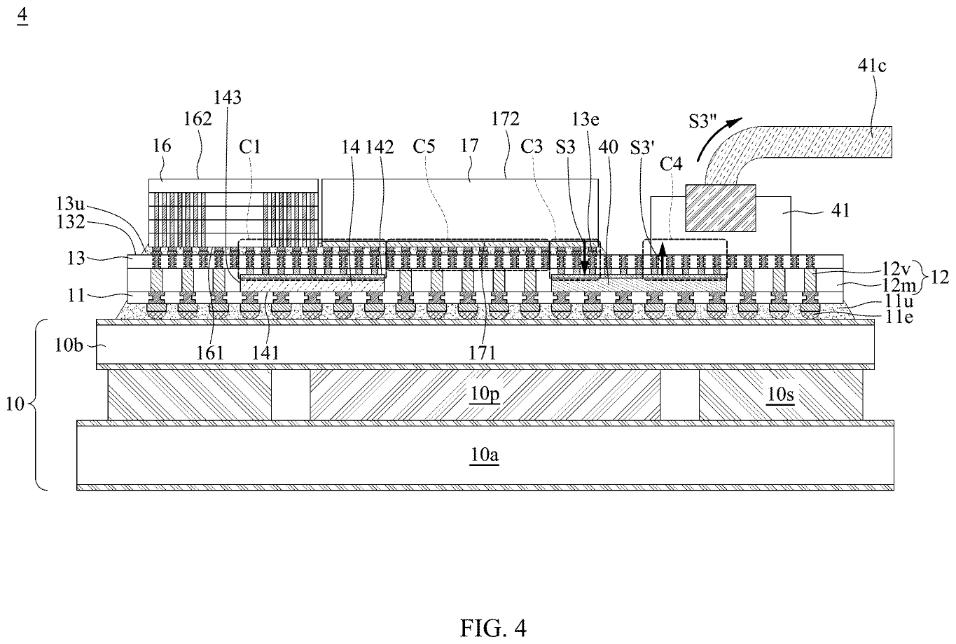

FIG. 4 illustrates a cross-sectional view of an example of an electronic device 4 according to some arrangements of the present disclosure. The electronic device 4 in FIG. 4 is similar to the electronic device 1 in FIG. 1 except that the bridge component 15 and the photonic component 18 in the electronic device 1 are replaced by a processor 40 and a connector 41.

The processor 40 and the connector 41 may be configured to perform data transmission (such as high-speed data transmission) between the electronic device 4 and external component(s). The processor 40 may include a digital signal processor, such as an ASIC, an FPGA, or another type of computing element or integrated circuit.

The interconnection structure 13 may include a circuit region C3 between the electronic component 17 and the processor 40, and a circuit region C4 between the connector 41 and the processor 40. The circuit region C3 may be configured to provide at least a part of the signal path S3 between the electronic component 17 and the processor 40. The circuit region C4 may be configured to provide at least a part of the signal path S3′ between the connector 41 and the processor 40.

The circuit region C3 and the circuit region C4 may have different circuit densities. For example, the circuit region C3 may have a circuit density higher than that of the circuit region C4. For example, the line width (e.g., the width of a line), the line spacing (e.g., the distance or the pitch between two adjacent lines), and/or the pad pitch (e.g., the distance or pitch between two adjacent pads) in the circuit region C3 may be less than those of the circuit region C4. In some arrangements, the circuit region C4 may form a SerDes or serializer/deserializer interface.

In some arrangements, the circuit region C4 may have a circuit density lower than that of the circuit region C1 in FIG. 1. In some arrangements, the circuit region C4 may have a circuit density higher than that of the circuit region C1 in FIG. 1.

The processor 40 may be configured to receive an electrical signal from the electronic component 17 (e.g., via the signal path S3), process the electrical signal, and generate a processed electrical signal for the connector 41 (e.g., via the signal path S3′). The processor 40 may include a transceiver that may be capable of converting parallel data to serial data and vice-versa. In some arrangements, the connector 41 may include a cable 41c. The processed electrical signal from the processor 40 may be transmitted from the electronic device 4 toward an external component through the cable 41c (e.g., via the signal path S3″).

In some arrangements, the signal path between the electronic component 17 and the connector 41 may include a vertical path (e.g., the signal path S3 via the interconnection structure 13) for transmitting the electrical signal from the electronic component 17 downwardly toward the processor 40 and a vertical path (e.g., the signal path S3′ via the interconnection structure 13) for transmitting the processed electrical signal from the processor 40 upwardly toward the connector 41. For example, the part of the signal paths S3 and S3′ provided by the processor 40 may include a vertical path. There may be no horizontal or lateral paths in the part of the signal paths S3 and S3′ provided by the processor 40. Therefore, the signal path between the electronic component 17 and the connector 41 can be short and signal propagation delay can be reduced.

In some arrangements, the signal may be transmitted and/or received by the connector 41 without passing downwardly along a lateral side of the processor 40.

In some arrangements, the processor 40 may be replaced with the bridge component 15 in FIG. 1 and the circuit region between the bridge component 15 and the connector 41 may form a SerDes or serializer/deserializer interface. The signal may be transmitted and/or received by the connector 41 without passing downwardly along a lateral side of the bridge component 15.

In some arrangements, the processor 40 may be replaced with the integrated component 30 in FIG. 3 and the circuit region between the integrated component 30 and the connector 41 may form a SerDes or serializer/deserializer interface. The signal may be transmitted and/or received by the connector 41 without passing downwardly along a lateral side of the integrated component 30.

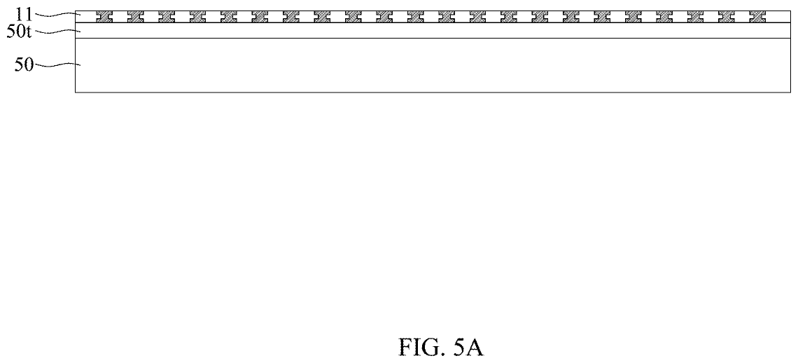

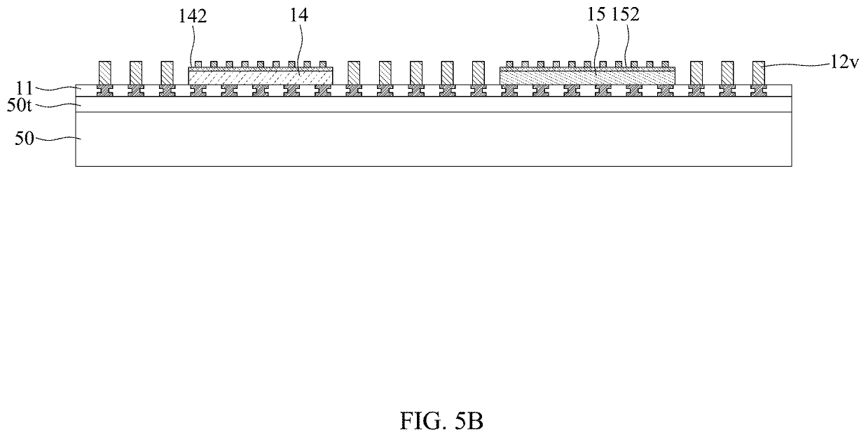

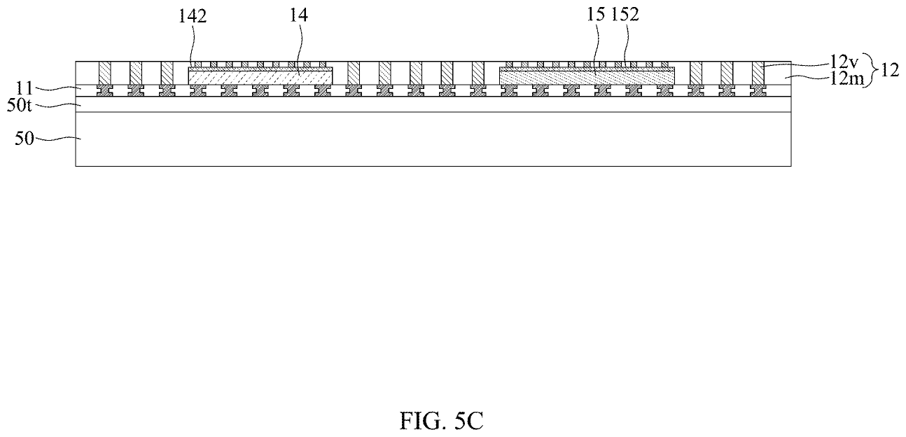

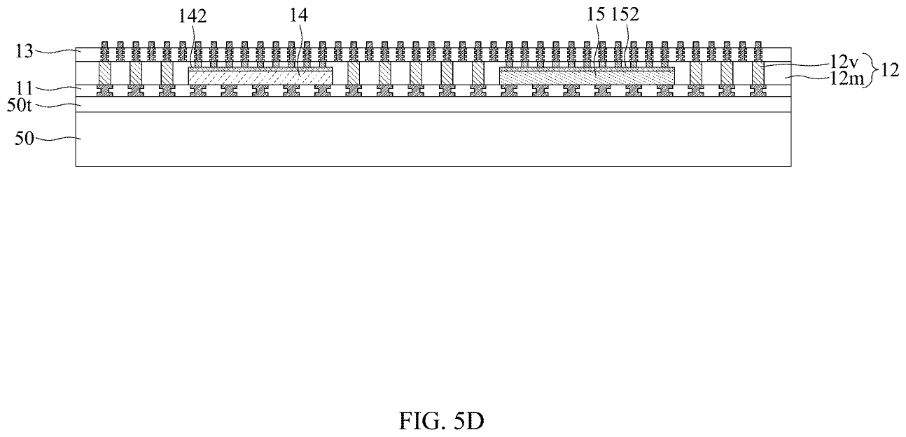

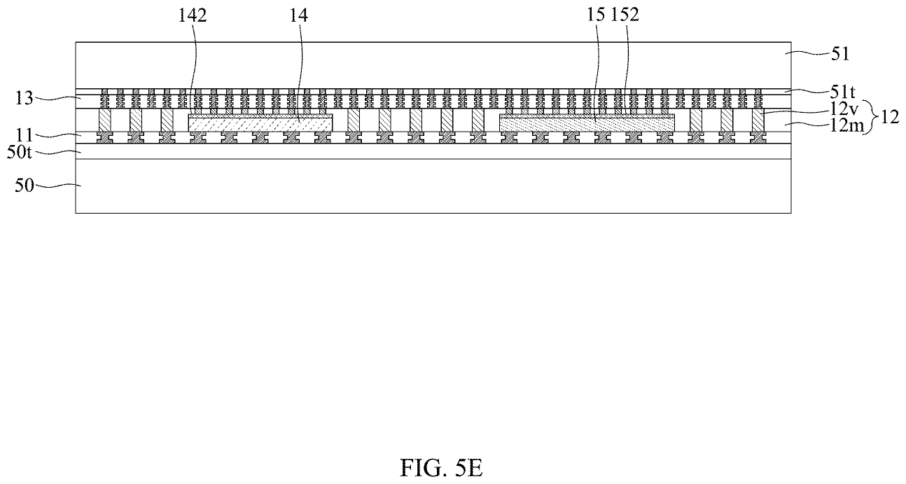

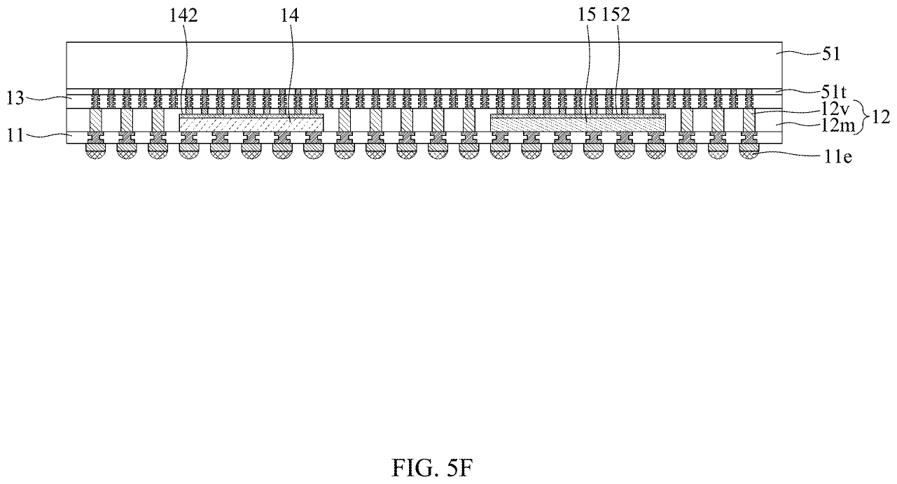

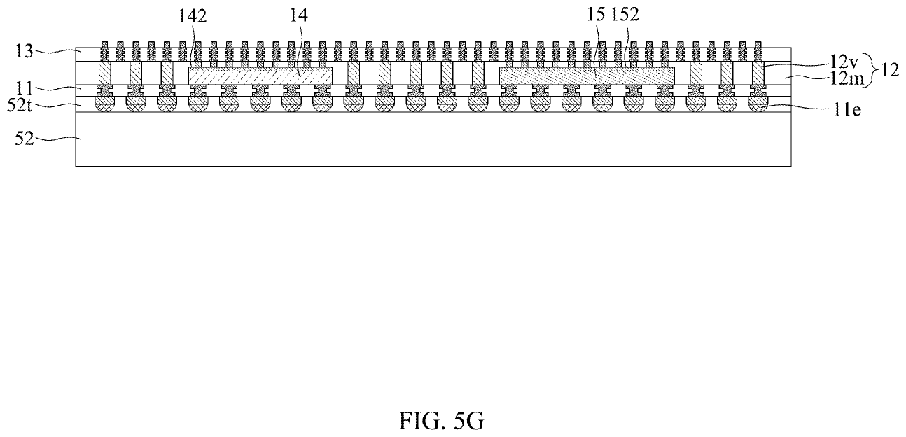

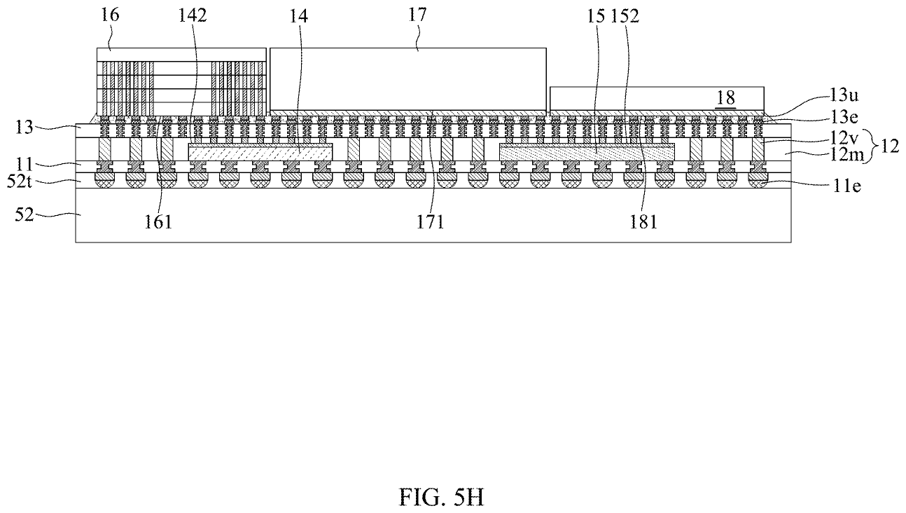

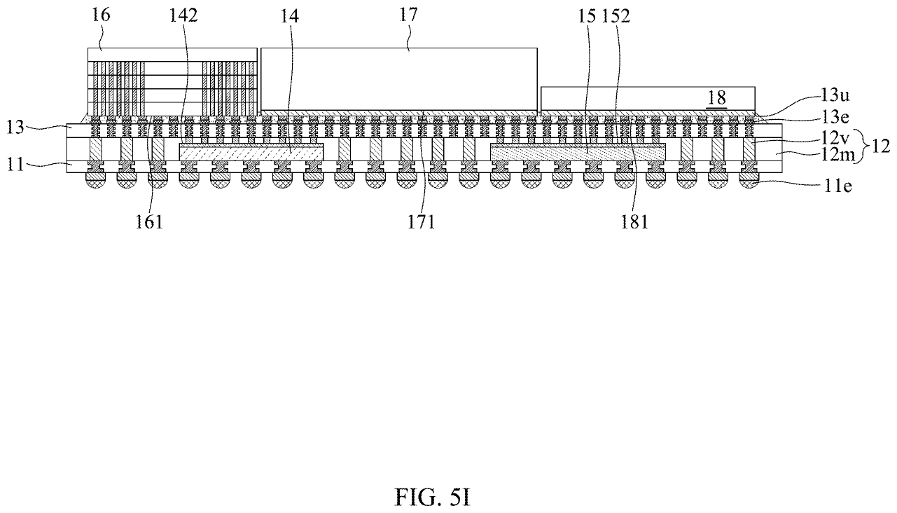

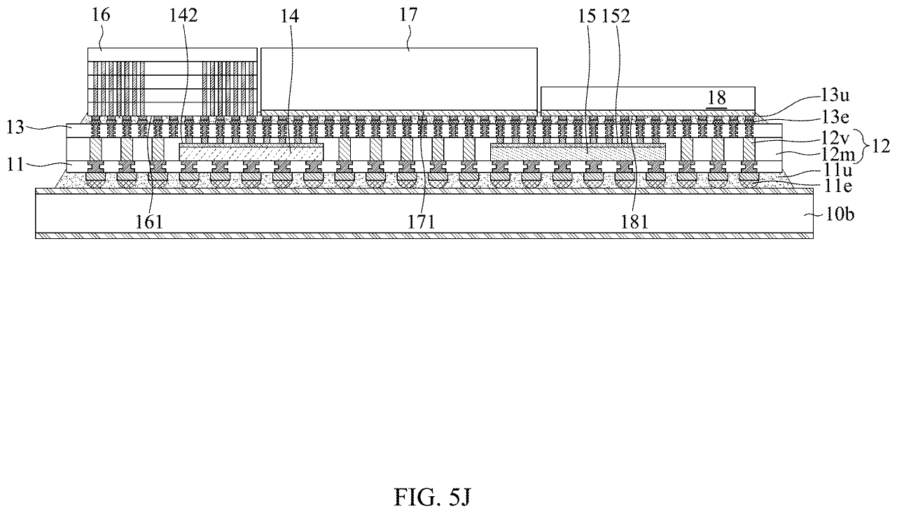

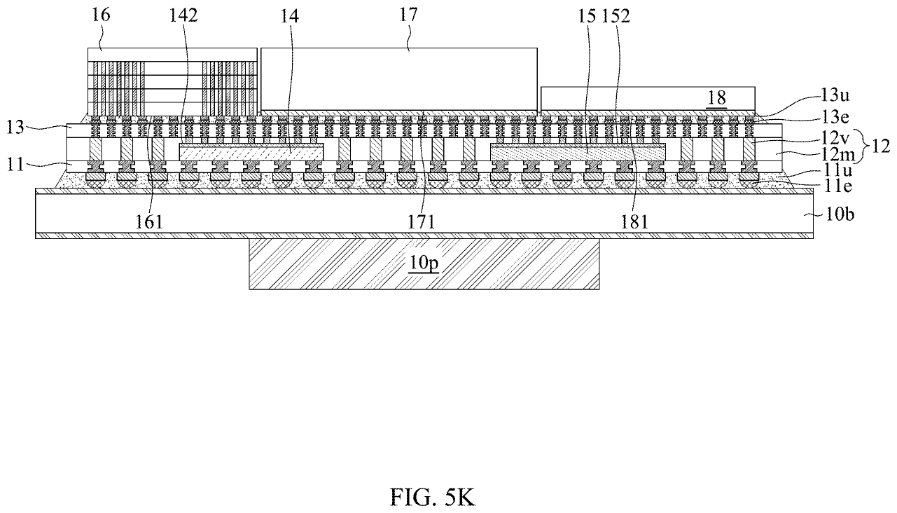

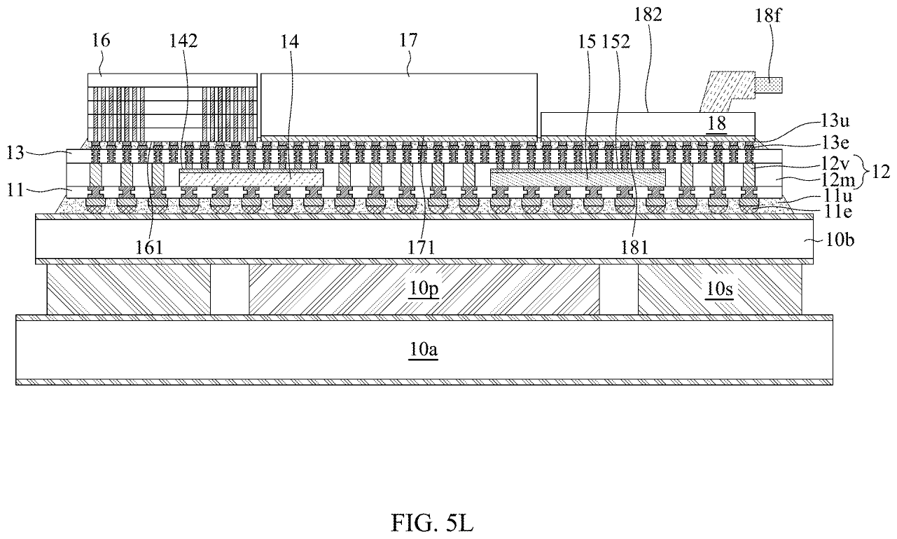

FIGS. 5A, 5B, 5C, 5D, 5E, 5F, 5G, 5H, 5I, 5J, 5K, and 5L illustrate cross-sectional views in one or more stages of a method of manufacturing an electronic device in accordance with an embodiment of the present disclosure. In some arrangements, the electronic device 1 may be manufactured through the operations described with respect to FIGS. 5A, 5B, 5C, 5D, 5E, 5F, 5G, 5H, 5I, 5J, 5K, and 5L.

Referring to FIG. 5A, a temporary carrier 50 may be provided. The interconnection structure 11 may be disposed over or on the temporary carrier 50. The interconnection structure 11 may be attached to the temporary carrier 50 through a tape 50t. In some arrangements, the interconnection structure 11 may be formed by an RDL manufacturing process.

Referring to FIG. 5B, the conductive elements 12v, the bridge component 14, and the bridge component 15 may be disposed or mounted over or on the interconnection structure 11. The interconnection layer (e.g., an RDL) may be disposed over or on the surface 142 of the bridge component 14 facing away from the interconnection structure 11. The active surface (such as the surface 152) of the bridge component 15 may face away from the interconnection structure 11. The interconnection layer (e.g., an RDL) may be disposed over or on the surface 152 of the bridge component 15.

Referring to FIG. 5C, the encapsulant 12m may be over or on the interconnection structure 11 to cover the conductive element 12v, the bridge component 14, and the bridge component 15. In some arrangements, the encapsulant 12m may be formed by molding, such as by printing, compressive molding, transfer molding, liquid encapsulant molding, vacuum lamination, spin coating, or other suitable processes.

In some arrangements, a planarization operation or a grinding operation may be performed to remove a portion of the encapsulant 12m to expose the top surfaces of the conductive elements 12v. The planarization operation or grinding operation may include an abrasive machining process that uses a grinding wheel or grinder, a chemical mechanical planarization (CMP) process, an etching process, or a laser direct ablation (LDA) process.

Referring to FIG. 5D, the interconnection structure 13 may be disposed over or on the interconnection structure 12. In some arrangements, the interconnection structure 13 may be formed by an RDL manufacturing process.

Referring to FIG. 5E, the interconnection structure 13 may be attached to a temporary carrier 51 through a tape 51t. A part of the interconnection structure 13 may be covered or surrounded by the tape 51t.

Referring to FIG. 5F, the tape 50t and the temporary carrier 50 in FIG. 5E may be removed from the interconnection structure 11. The electrical contacts 11e may be disposed over or on the interconnection structure 11.

Referring to FIG. 5G, the interconnection structure 11 may be attached to a temporary carrier 52 through a tape 52t. A part of the electrical contacts 11e may be covered or surrounded by the tape 52t. The tape 51t and the temporary carrier 51 in FIG. 5F may be removed from the interconnection structure 13.

Referring to FIG. 5H, the electronic component 16, the electronic component 17, and the photonic component 18 may be disposed over or on the interconnection structure 13. The electronic component 16, the electronic component 17, and the photonic component 18 may each be faced-down and electrically connected with the interconnection structure 13 through the electrical contacts 13e. For example, the active surfaces (such as the surfaces 161, 171, and 181) thereof may face toward the interconnection structure 13. The underfill 13u may be formed to cover or encapsulate the electrical contacts 13e.

Referring to FIG. 5I, a singulation may be performed to separate out individual structures in FIG. 5H. The singulation may be performed by, for example, using a dicing saw, laser, or other appropriate cutting technique. The tape 52t and the temporary carrier 52 in FIG. 5H may be removed from the interconnection structure 11.

Referring to FIG. 5J, the structure from FIG. 5I may be disposed over or on the substrate 10b and electrically connected to the substrate 10b through the electrical contacts 11e. The underfill 11u may be formed to cover or encapsulate the electrical contacts 11e.

Referring to FIG. 5K, the power regulating device 10p may be disposed over or on a surface of the substrate 10b opposite to the structure from FIG. 5I.

Referring to FIG. 5L, the structure from FIG. 5K may be disposed over or on the substrate 10a and operatively coupled (e.g., mated) to the substrate 10a using the connector 10s. The optical fiber 18f may be coupled to the backside surface (such as the surface 182) of the photonic component 18 through, for example, an optical grating and/or an optical waveguide.

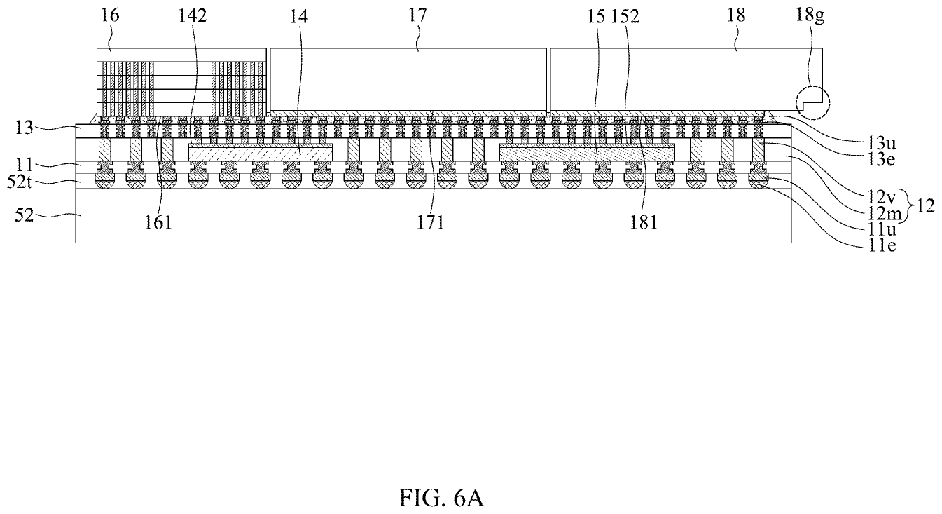

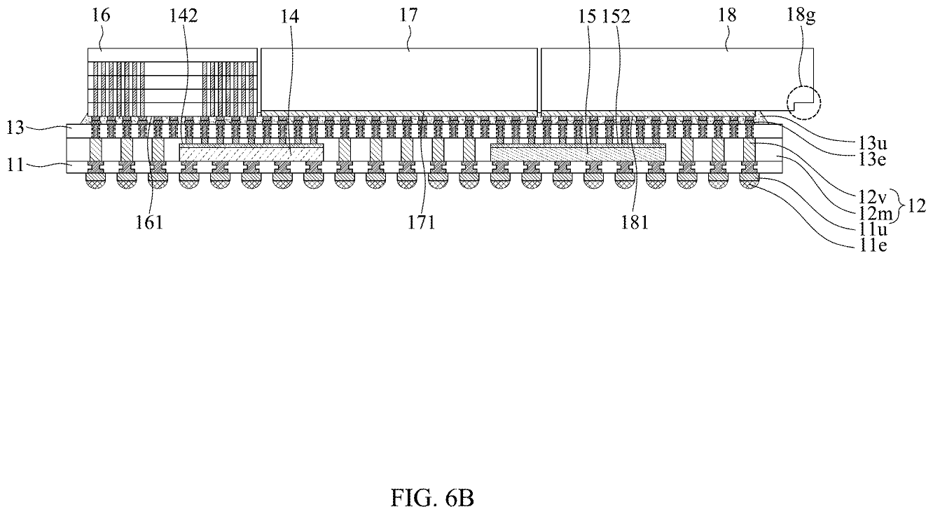

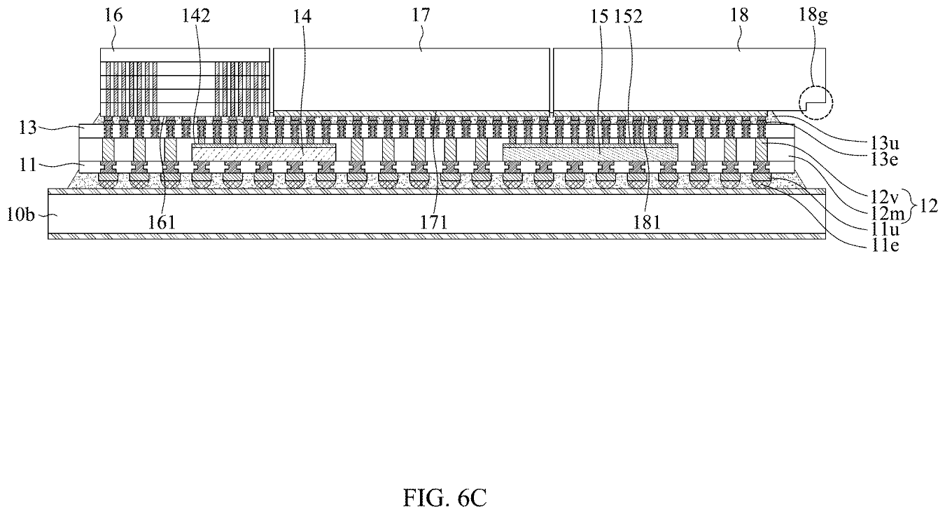

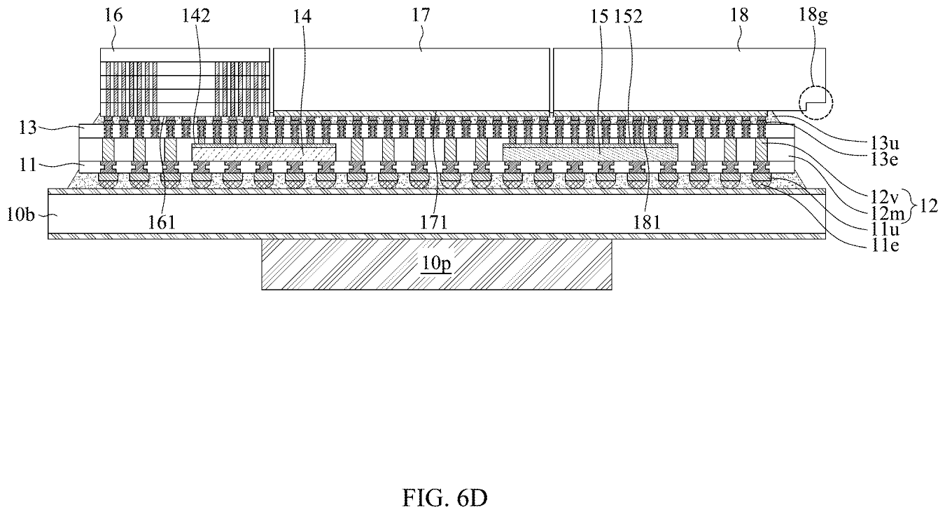

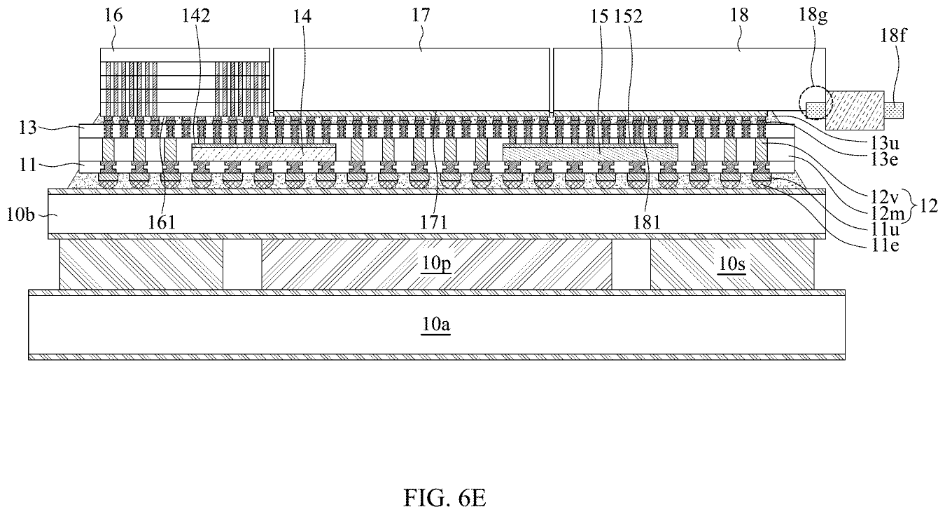

FIGS. 6A, 6B, 6C, 6D, and 6E illustrate cross-sectional views in one or more stages of a method of manufacturing an electronic device in accordance with an embodiment of the present disclosure. In some arrangements, the electronic device 2 may be manufactured through the operations described with respect to FIGS. 5A, 5B, 5C, 5D, 5E, 5F, 5G, and FIGS. 6A, 6B, 6C, 6D, and 6E.

Referring to FIG. 6A, the operation in FIG. 6A may be subsequent to the operations in FIGS. 5A, 5B, 5C, 5D, 5E, 5F, and 5G. The photonic component 18 may include the groove 18g.

The operations in FIGS. 6B, 6C, 6D, and 6E may be similar to the operations in FIGS. 5I, 5J, 5K, and 5L. Therefore, some details may correspond to the paragraphs above, and a description thereof is not repeated hereinafter for conciseness.

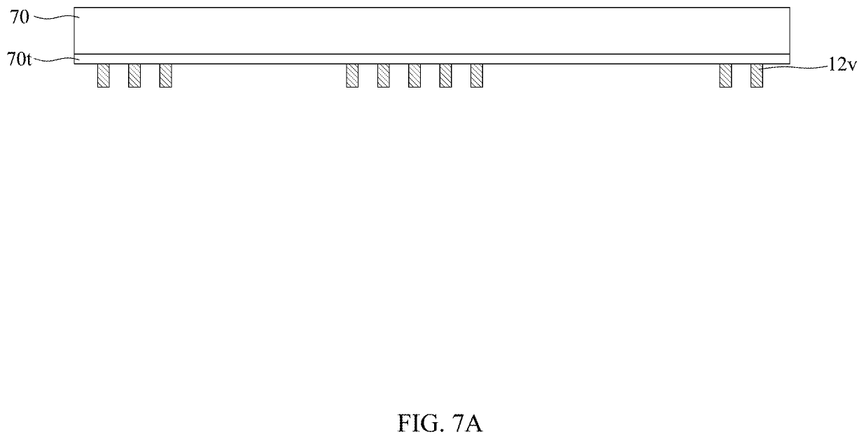

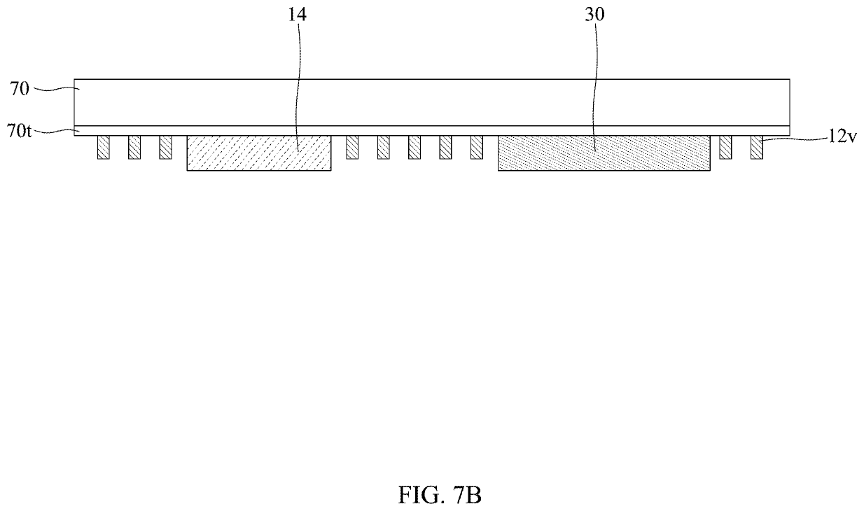

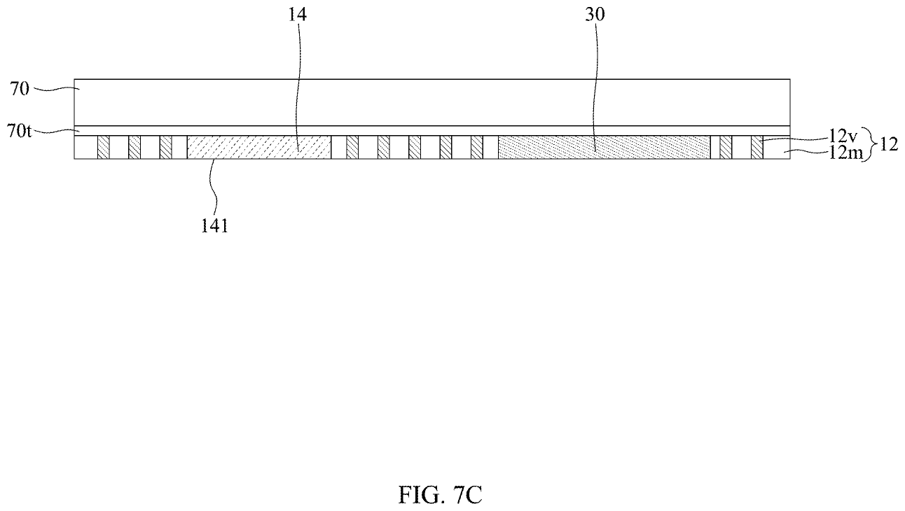

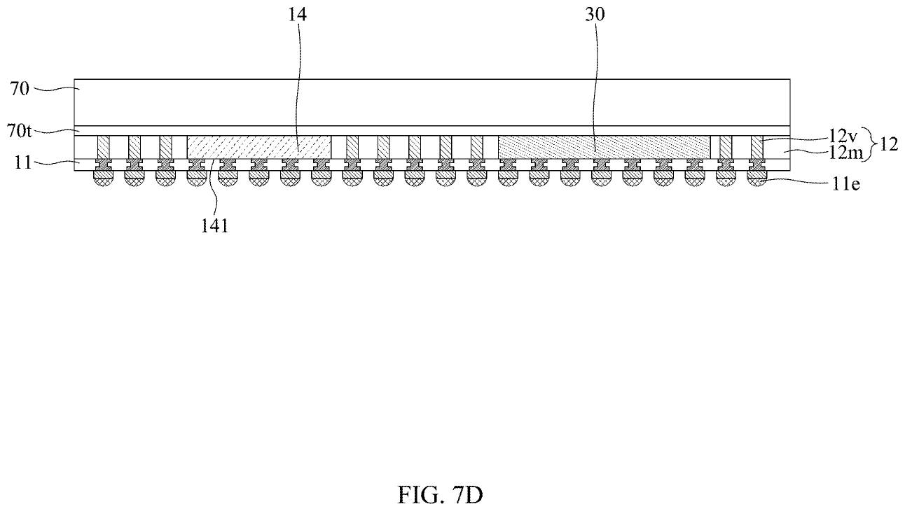

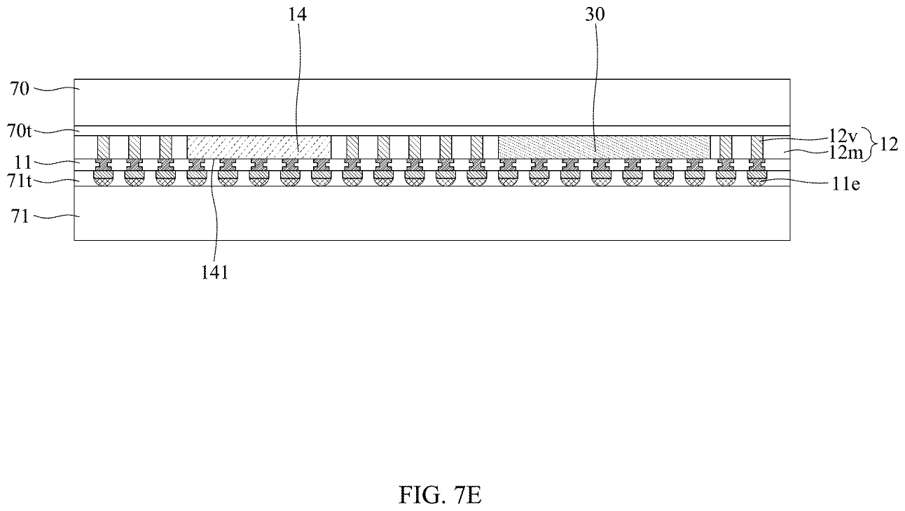

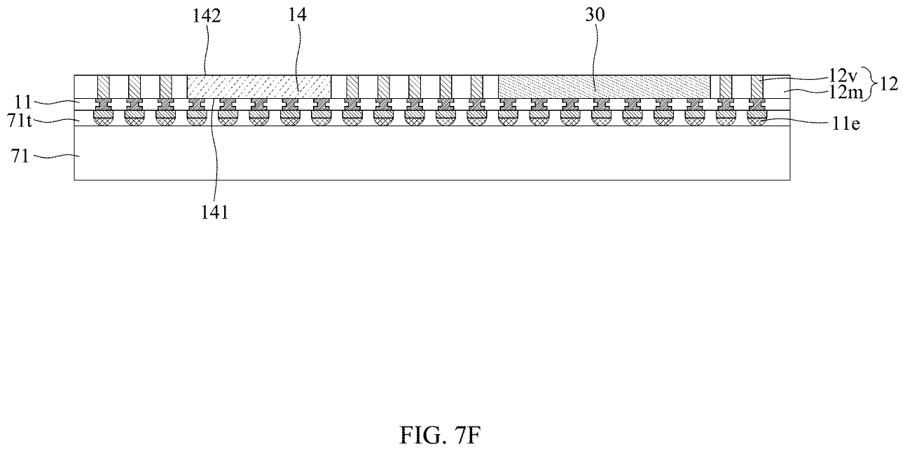

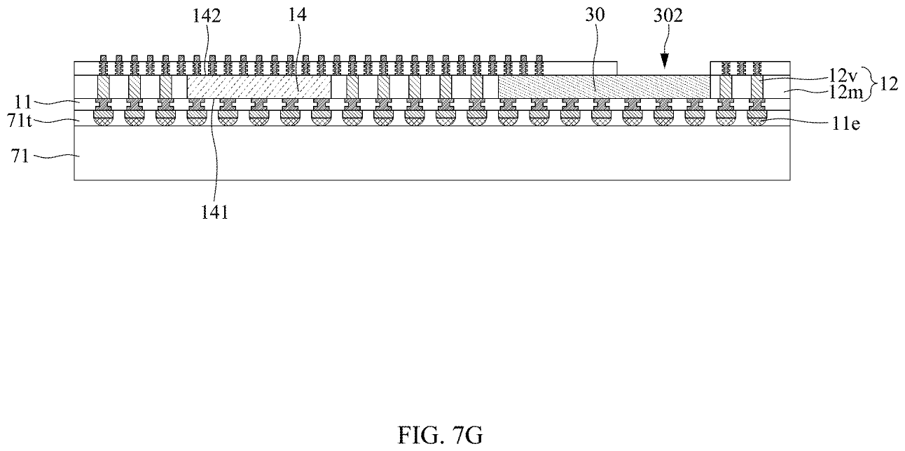

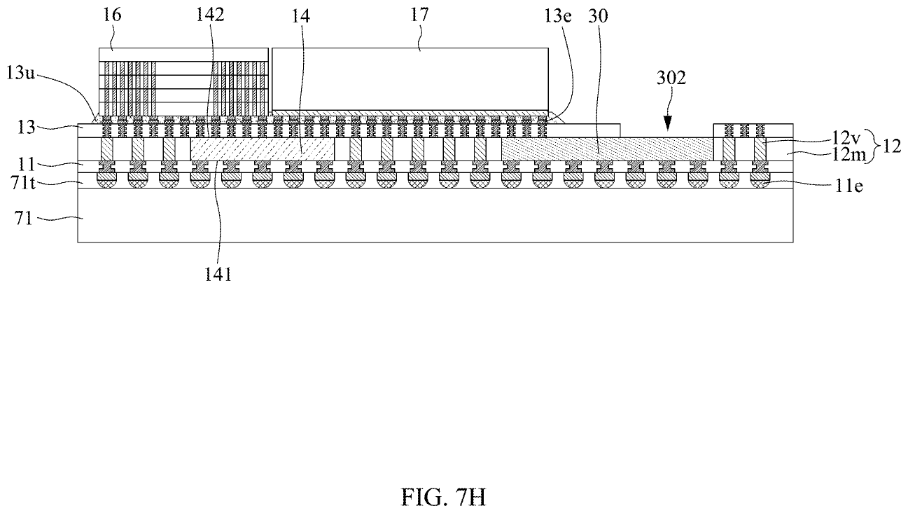

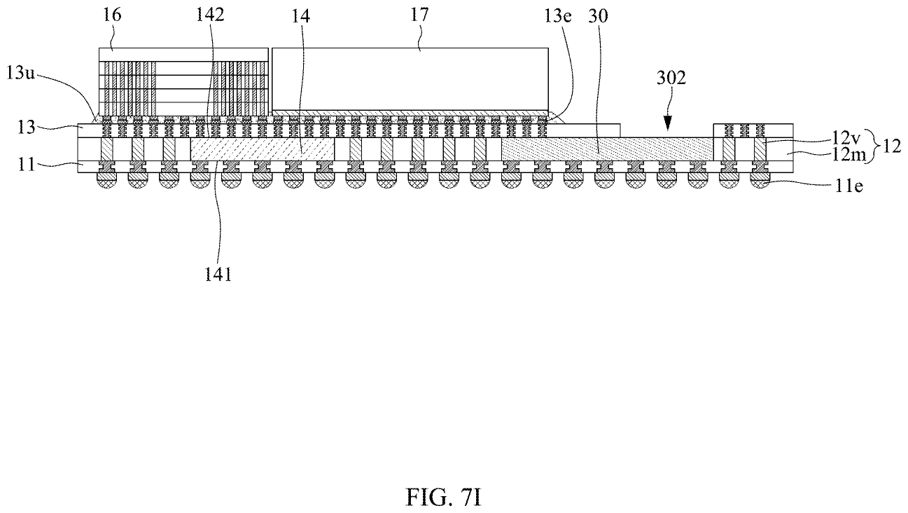

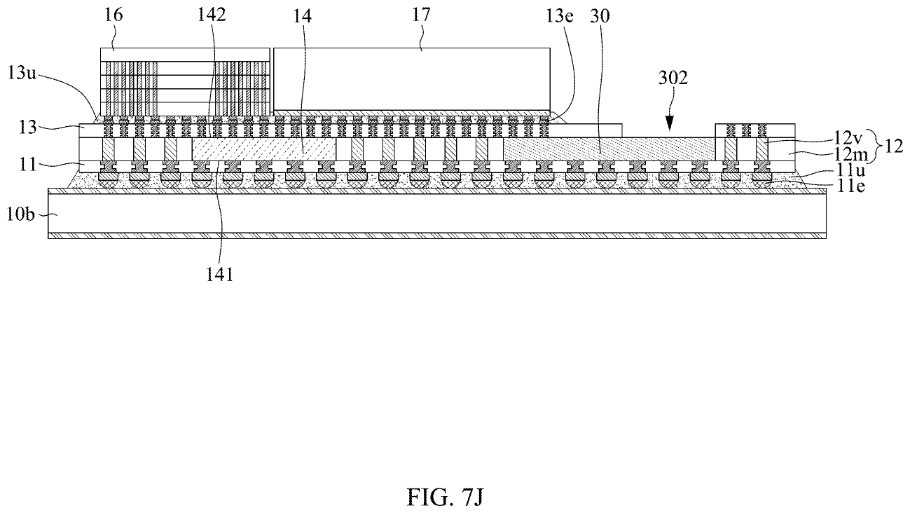

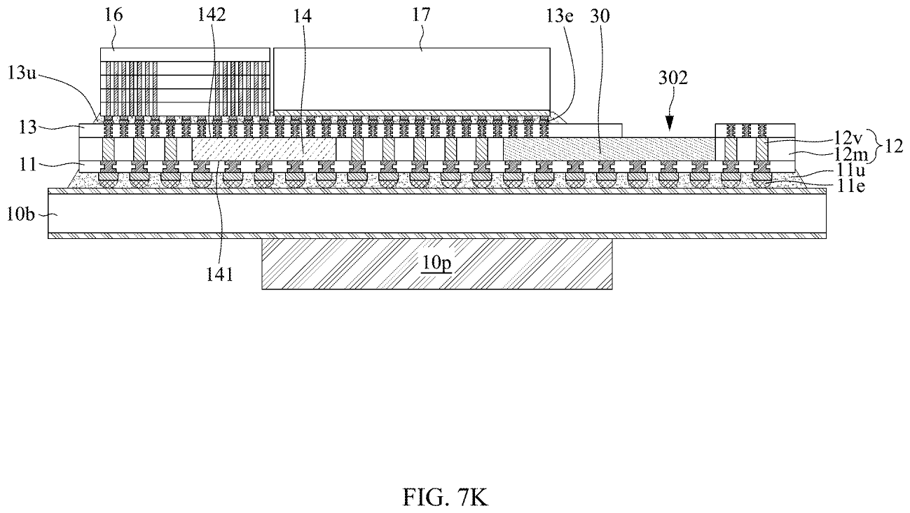

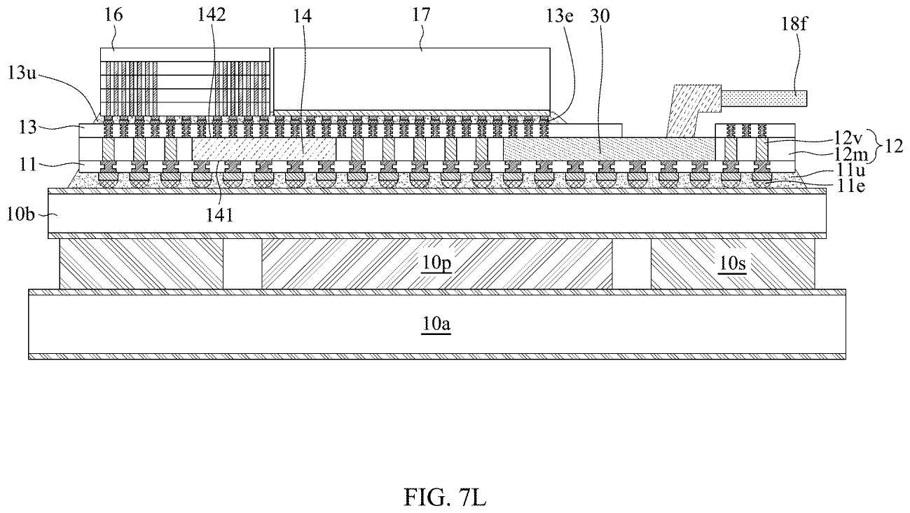

FIGS. 7A, 7B, 7C, 7D, 7E, 7F, 7G, 7H, 7I, 7J, 7K, and 7L illustrate cross-sectional views in one or more stages of a method of manufacturing an electronic device in accordance with an embodiment of the present disclosure. In some arrangements, the electronic device 3 may be manufactured through the operations described with respect to FIGS. 7A, 7B, 7C, 7D, 7E, 7F, 7G, 7H, 7I, 7J, 7K, and 7L.

Referring to FIG. 7A, a temporary carrier 70 may be provided. The conductive elements 12v may be disposed over or on the temporary carrier 70. The conductive elements 12v may be attached to the temporary carrier 70 through a tape 70t.

Referring to FIG. 7B, the bridge component 14 and the integrated component 30 may be attached to the temporary carrier 70 through the tape 70t.

Referring to FIG. 7C, the encapsulant 12m may be over or on the temporary carrier 70 to cover the conductive element 12v, the bridge component 14, and the integrated component 30. In some arrangements, a planarization operation or a grinding operation may be performed to remove a portion of the encapsulant 12m to expose the top surfaces of the conductive elements 12v.

Referring to FIG. 7D, the interconnection structure 11 may be disposed over or on the conductive element 12v, the bridge component 14, and the integrated component 30. The electrical contacts 11e may be disposed over or on the interconnection structure 11.

Referring to FIG. 7E, the structure from FIG. 7D may be attached to a temporary carrier 71 through a tape 71t. A part of the electrical contacts 11e may be covered or surrounded by the tape 71t.

Referring to FIG. 7F, the tape 70t and the temporary carrier 70 in FIG. 7E may be removed from the conductive element 12v, the bridge component 14, and the integrated component 30.

Referring to FIG. 7G, the interconnection structure 13 may be disposed over or on the conductive element 12v, the bridge component 14, and the integrated component 30. In some arrangements, the interconnection structure 13 may be formed by an RDL manufacturing process. A part of the interconnection structure 13 may be removed to expose a part of the surface 302 of the integrated component 30.

Referring to FIG. 7H, the electronic component 16 and the electronic component 17 may be disposed over or on the interconnection structure 13.

Referring to FIG. 7I, a singulation may be performed to separate out individual structures in FIG. 7H. The tape 71t and the temporary carrier 71 in FIG. 7H may be removed from the interconnection structure 11.

Referring to FIG. 7J, the structure from FIG. 7I may be disposed over or on the substrate 10b and electrically connected to the substrate 10b through the electrical contacts 11e. The underfill 11u may be formed to cover or encapsulate the electrical contacts 11e.

Referring to FIG. 7K, the power regulating device 10p may be disposed over or on a surface of the substrate 10b opposite to the structure of FIG. 7I.

Referring to FIG. 7L, the structure of FIG. 7K may be disposed over or on the substrate 10a and operatively coupled (e.g., mated) to the substrate 10a using the connector 10s. The optical fiber 18f may be coupled to the active surface (such as the surface 302) of the integrated component 30 through, for example, an optical grating and/or an optical waveguide.

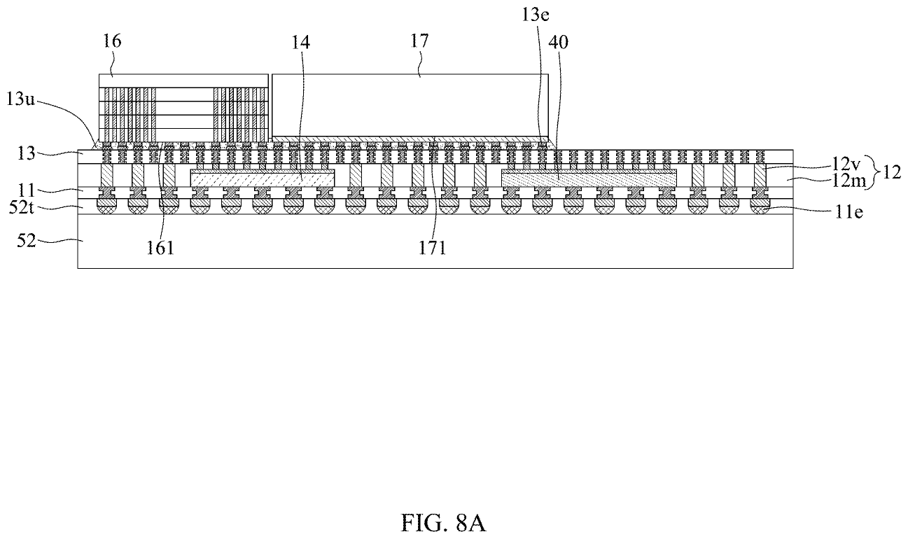

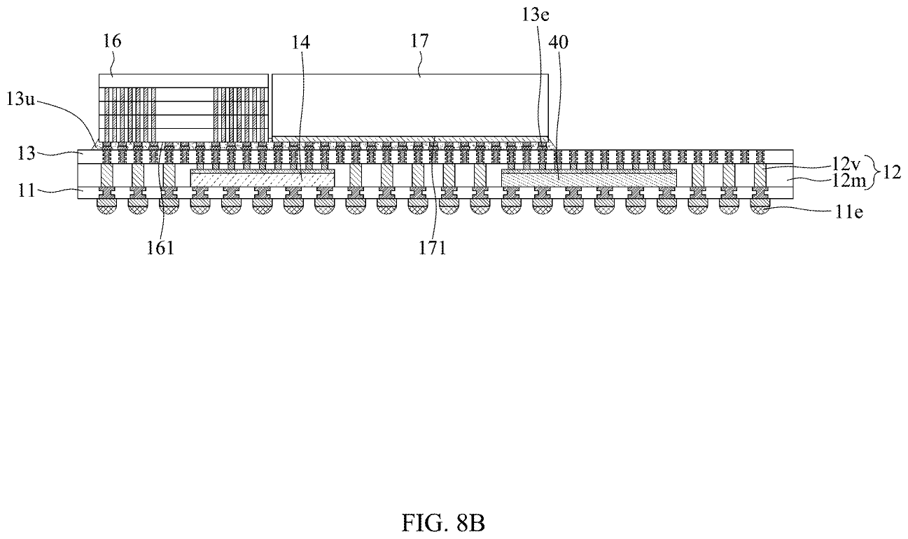

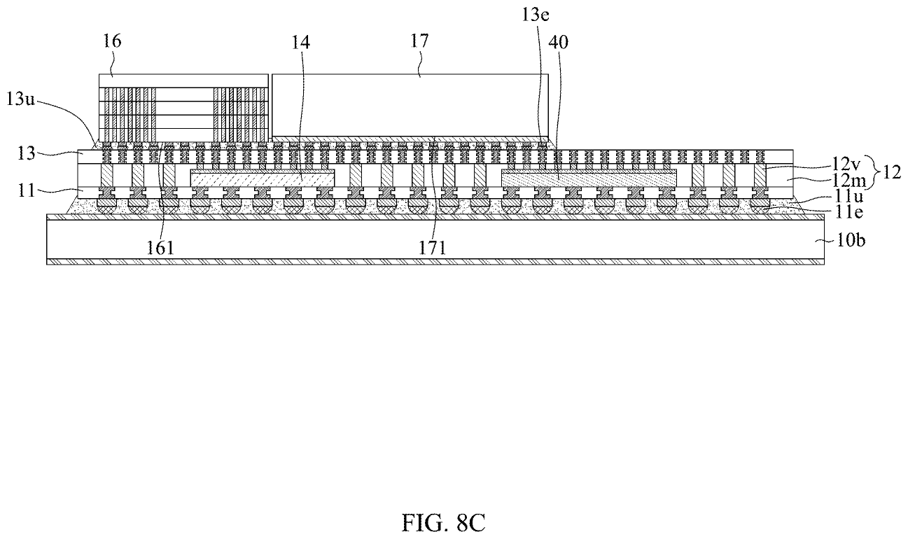

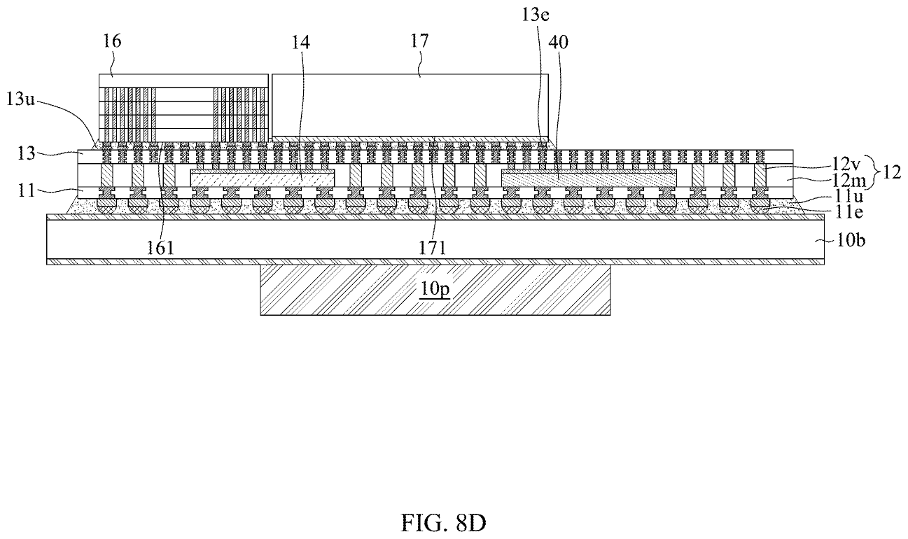

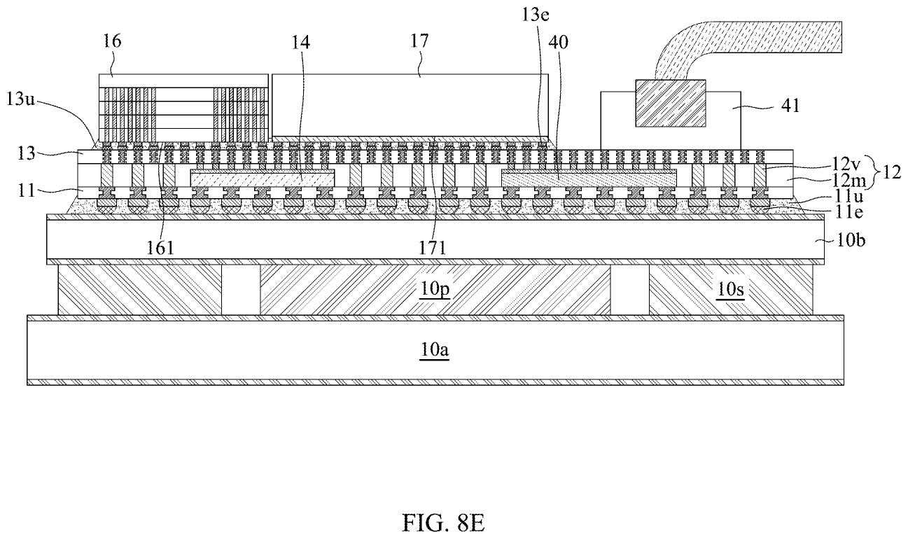

FIGS. 8A, 8B, 8C, 8D, and 8E illustrate cross-sectional views in one or more stages of a method of manufacturing an electronic device in accordance with an embodiment of the present disclosure. In some arrangements, the electronic device 2 may be manufactured through the operations described with respect to FIGS. 5A, 5B, 5C, 5D, 5E, 5F, 5G, and FIGS. 8A, 8B, 8C, 8D, and 8E.

Referring to FIG. 8A, the operation in FIG. 8A may be subsequent to the operations in FIGS. 5A, 5B, 5C, 5D, 5E, 5F, and 5G. The electronic component 16 and the electronic component 17 may be disposed over or on the interconnection structure 13.

The operations in 8B, 8C, and 8D may be similar to the operations in FIGS. 5I, 5J, and 5K. Therefore, some details may correspond to the paragraphs above, and a description thereof is not repeated hereinafter for conciseness.

Referring to FIG. 8E, the connector 41 may be disposed over or on the interconnection structure 13.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first component;
a second component; and
a first bridge component configured to electrically connect the first component with the second component,
wherein the first component is configured to transmit a first signal downwardly without passing the first bridge component and the second component is configured to transmit/receive a second signal to/from outside of the electronic device, and wherein a transmission speed of the second signal is higher than a transmission speed of the first signal.

2. The electronic device of claim 1, wherein the first bridge component comprises an active component.

3. The electronic device of claim 2, wherein the second signal is transmitted through an active circuit of the first bridge component.

4. The electronic device of claim 2, wherein the first bridge component comprises an electronic integrated circuit (EIC), a photonic integrated circuit (PIC), an integrated electronic-photonic integrated circuit (EPIC), an input/output (I/O) die, or a combination thereof.

5. The electronic device of claim 2, wherein the second component comprises a PIC or an I/O connector.

6. The electronic device of claim 1, wherein the second signal is transmitted between the first component and the second component through the first bridge component.

7. The electronic device of claim 1, further comprising:
a third component; and
a second bridge component configured to electrically connect the first component with the third component.

8. The electronic device of claim 7, further comprising:
an encapsulant at least partially covering the first bridge component and the second bridge component, wherein the encapsulant supports the first component, the second component, and the third component.

9. An electronic device, comprising:
a first component;
a second component; and
a first bridge component configured to electrically connect the first component with the second component,
wherein a first circuit region between the first component and the first bridge component has a first density and a second circuit region between the second component and the first bridge component has a second density lower than the first density.

10. The electronic device of claim 9, wherein a signal is transmitted or received by the second component without passing downwardly along a lateral side of the first bridge component.

11. The electronic device of claim 9, further comprising:
a third component; and
a second bridge component configured to electrically connect the first component with the third component.

12. The electronic device of claim 11, wherein a third circuit region between the first component, the third component and the second bridge component has a third density lower than the first density of the first circuit region.

13. The electronic device of claim 11, further comprising:
a fourth circuit region under the first component and distinct from the first circuit region, wherein the fourth circuit region has a fourth density different from the first density of the first circuit region.

14. The electronic device of claim 12, wherein a data transmission speed of the first circuit region is higher than a data transmission speed of the third circuit region.

15. The electronic device of claim 9, wherein the first bridge component comprises an electrical transmission region and an optical transmission region, wherein the electrical transmission region functions as a bridge circuit between the first component and the optical transmission region.

16. The electronic device of claim 15, further comprising:
a circuit layer between the first component and the first bridge component, wherein the optical transmission region is exposed from the circuit layer.

17. An electronic device, comprising:
an encapsulant;
a first bridge component at least partially embedded in the encapsulant;
a redistribution layer (RDL) disposed over the encapsulant; and
a first electronic component disposed over the RDL,
wherein the RDL is configured to provide a first signal path between the first electronic component and the first bridge component, and configured to provide a second signal path between the first bridge component and a component external to the electronic device without passing through the encapsulant.

18. The electronic device of claim 17, further comprising:
a transducer disposed over the first bridge component and located at the second signal path.

19. The electronic device of claim 18, wherein the transducer comprises an optical/electrical (O/E) converter.

20. The electronic device of claim 18, further comprising:
a second electronic component disposed over the RDL; and
a second bridge component at least partially embedded in the encapsulant and electrically connected the second electronic component with first electronic component.
